(19) United States
(12) Patent Application Publication
(10) Pub. No.: US 2010/0067559 A1
(43) Pub. Date: Mar. 18, 2010

(54) LASER DIODE DEVICE, OPTICAL APPARATUS AND DISPLAY APPARATUS

(75) Inventors: Daijiro INOUE, Kyoto-shi (JP); Yasuyuki Bessho, Uji-shi (JP); Masayuki Hata, Kadoma-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/557,138

(22) Filed: Sep. 10, 2009

(30) Foreign Application Priority Data
Sep. 12, 2008 (JP) 2008-234145
Aug. 27, 2009 (JP) 2009-196267

(51) Int. Cl. H01S 5/00

(52) U.S. Cl. 372/50.121

(57) ABSTRACT

A laser diode device includes a first laser diode element, a second laser diode element and a third laser diode element having a longer lasing wavelength than the first and second 6 laser diode elements. The first, second and third laser diode elements are arranged in a package, and the third laser diode element is not electrically connected to the first and second laser diode elements.

### CROSS-REFERENCE TO RELATED APPLICATIONS

The priority application numbers JP2008-234145, Laser Diode Device, Sep. 12, 2008, Daijiro Inoue et al, JP2009-196267, Laser Diode Device, Optical Apparatus and Display Apparatus, Aug. 27, 2009, Daijiro Inoue et al, upon which this patent application is based are hereby incorporated by reference.

### BACKGROUND OF THE INVENTION

1. Field of the Invention

The present invention relates to a laser diode device, an optical apparatus and a display apparatus, and more particularly, it relates to a laser diode device comprising a first laser diode element, a second laser diode element and a third laser diode element, and an optical apparatus and a display apparatus each comprising the same.

2. Description of the Background Art

A laser diode device comprising a first laser diode element, a second laser diode element and a third laser diode element is known in general, as disclosed in Japanese Patent Laying-Open No. 2001-230502, for example.

FIG. 22 is a sectional view showing a structure of a conventional laser diode device. FIG. 23 is a schematic diagram showing an electrical connection state of the conventional laser diode device shown in FIG. 22. Referring to FIGS. 22 and 23, in a conventional laser diode device 700 described in the aforementioned Japanese Patent Laying-Open No. 2001-230502, a monolithic laser diode element 790 including a green laser diode element 720 (second laser diode element) capable of emitting green light having an lasing wavelength of about 520 nm and a red laser diode element 730 (third laser diode element) capable of emitting red light having an lasing wavelength of about 650 nm is set on a surface of a blue laser diode element 710 (first laser diode element) capable of emitting blue light having an lasing wavelength of about 400 nm. The blue laser diode element 710 has a structure in which an n-type cladding layer 712, an active layer 713 and a p-type cladding layer 714 are stacked in this order on a surface of a substrate 711. The green laser diode element 720 has a structure in which an n-type cladding layer 722, an active layer 723 and a p-type cladding layer 724 are stacked in this order on a surface of a substrate 791 on a direction Y1 side. The red laser diode element 730 has a structure in which an n-type cladding layer 732, an active layer 733 and a p-type cladding layer 734 are stacked in this order on a surface of the substrate 791 on a direction Y2 side. Current blocking layers 715, 725 and 735 are formed to cover planar portions of the p-type cladding layer 714, 724 and 734 and side surfaces of ridges, respectively. P-side electrodes 716, 726 and 736 are formed on surfaces of the ridges of the p-type cladding layer 714, 724 and 734 and surfaces of the current blocking layers 715, 725 and 735, respectively. The p-side electrode 726 side of the green laser diode element 720 is bonded to an upper surface of the blue laser diode element 710 on the direction Y1 side through a fusion layer 792. The p-side electrode 736 side of the red laser diode element 730 is bonded to the upper surface of the blue laser diode element 710 on the direction Y2 side through a fusion layer 793. An n-side electrode 794 is formed on a surface of the substrate 791.

A metal layer 795 is formed on the surface of the substrate 711 on the direction Y2 side. This metal layer 795 is an n-side electrode of the blue laser diode element 710 and is electrically connected to the p-side electrode 736 of the red laser diode element 730 through the fusion layer 793. In other words, the n-side electrode (metal layer 795) of the blue laser diode element 710 and the p-side electrode 736 of the red laser diode element share a lead terminal 706c described later through a wire 707c described later to supply electricity.

An insulating layer 796 is formed on the surface of the substrate 711 on the direction Y1 side. A metal layer 797 is formed on a surface of the insulating layer 796. This metal layer 797 is electrically connected to the p-side electrode 726 of the green laser diode element 720 through the fusion layer 792. The p-side electrode 716 side of the blue laser diode element 710 is bonded to a support base 704a which is a part of a conductive package 704 through a fusion layer 798.

The support base 704a is integrally bonded on a stem body 704b. The stem body 704b is mounted with lead terminals 706a, 706b and 706c successively from on the direction Y1 side through insulating rings 5. The lead terminals 706a, 706b and 706c are connected to first ends of wires 707a, 707band 707c, respectively. Second ends of the wires 707a, 707b and 707c are connected to the metal layer 797, the n-side electrode 794 and the metal layer 795, respectively. A terminal 706g is electrically connected to the stem body 704b.

Thus, in the conventional laser diode device 700 described in Japanese Patent Laying-Open No. 2001-230502, the p-side electrode 736 of the red laser diode element 730 is so formed as to electrically connected to the n-side electrode (metal layer 795) of the blue laser diode element 710 and the n-side electrode 794 of the red laser diode element 730 electrically connected to the n-side electrode 794 of the green laser diode element (these two elements share the same electrode), as shown in FIG. 23.

In the laser diode device 700 disclosed in the aforementioned Japanese Patent Laying-Open No. 2001-230502, however, the blue laser diode element 710 and the green laser diode element 720 having shorter lasing wavelengths are not electrically separated from the red laser diode element 730 having a longer lasing wavelength. The red laser diode element 730 having the longer lasing wavelength is made of a material having a small band gap and hence has a lower device resistance to easily flow a current through the active layer 733 lasing red light, as compared with the blue laser diode element 710 and the green laser diode element 720 having the shorter lasing wavelengths. Therefore, a surge current generated when operating the blue laser diode element 710 and the green laser diode element 720 having high operation voltages easily flows, thereby disadvantageously deteriorating the red laser diode element 730. In a laser diode device according to a third embodiment described in the aforementioned Japanese Patent Laying-Open No. 2001-230502, although a laser diode element having a shorter lasing wavelength is separated from other laser diode element, the aforementioned problem is not solved.

### SUMMARY OF THE INVENTION

A laser diode device according to a first aspect of the present invention comprises a first laser diode element, a second laser diode element and a third laser diode element having a longer lasing wavelength than the first and second laser diode elements, wherein the first, second and third laser diode elements are arranged in a package, and the third laser diode element is not electrically connected to the first and second laser diode elements.

In the laser diode device according to the first aspect of the present invention, as hereinabove described, the third laser diode element having the longer lasing wavelength than the first and second laser diode elements is not electrically connected to the first and second laser diode elements, whereby the third laser diode element, which is made of a material with a smaller band gap than the first and second laser diode elements and hence has a low device resistance to easily flow a current through the active layer, can be electrically separated, and hence the third laser diode element having the longer lasing wavelength can be inhibited from deterioration due to a surge current generated when operating the first and second laser diode elements.

In the aforementioned laser diode device according to the first aspect, each of the first, second and third laser diode elements preferably includes a first electrode and a second electrode, and the first and second electrodes of the third laser diode element are preferably provided separately from the first and second electrodes of the first laser diode element and the first and second electrodes of the second laser diode element. According to this structure, the third laser diode element can be easily electrically separated from the first and second laser diode elements, and hence the surge current from the first and second laser diode elements can be inhibited from flowing through the third laser diode element. Separate power sources are connected to the respective electrodes, whereby different arbitrary voltages can be independently applied to the respective electrodes.

In the aforementioned laser diode device according to the first aspect, the first laser diode element is preferably a blue laser diode element, the second laser diode element is preferably a green laser diode element, and the third laser diode element is preferably a red laser diode element. According to this structure, the red laser diode element, which is made of the material with the small band gap and hence has the low device resistance to easily flow-a current through the active layer, can be electrically separated in the RGB three-wavelength laser diode device, and hence the red laser diode element can be inhibited from deterioration due to a surge current generated when operating the blue and green laser diode elements having higher operation voltages.

In the aforementioned laser diode device according to the first aspect, at least one of the first and second laser diode elements and the third laser diode element preferably substantially simultaneously lase or alternately lase in time series. As to the “substantially simultaneously lase”, it is not required that start of the lasing of at least one of the first and second laser diode elements always coincides with start of the lasing of the third laser diode element, so far as one of the laser diode elements lases during the other laser diode element lases. When at least one of the first and second laser diode elements and the third laser diode element substantially simultaneously lase or alternately lase in time series, a surge current caused in the first or second laser diode element is radiated outside through a portion having a low resistance. In other words, a surge current easily flows through the third laser diode element which has a small band gap and hence has a low device resistance. On the other hand, the third laser diode element is not electrically connected to the first and second laser diode elements in this invention, whereby the third laser diode element during operation can be effectively inhibited from deterioration due to the surge current.

In the aforementioned laser diode device according to the first aspect, the package is preferably conductive, the third laser diode element preferably includes at least a first electrode, and the first electrode of the third laser diode element is preferably electrically connected to the package. According to this structure, a surge current caused by static electricity or the like is temporarily held in the conductive package, whereby the surge current can be inhibited from rapidly flowing through the third laser diode element. Thus, deterioration of the third laser diode element can be suppressed.

In this case, the package is preferably grounded. According to this structure, a surge current can be promptly released from the laser diode device, and hence the surge current can be reliably inhibited from rapidly flowing through the third laser diode element.

In the aforementioned laser diode device according to the first aspect, the first, second and third laser diode elements are preferably arranged on a surface of a first support substrate having an insulating property with prescribed intervals. According to this structure, the third laser diode element can be easily electrically separated from the first and second laser diode elements by the first support substrate having the insulating property.

In the aforementioned laser diode device according to the first aspect, the first and second laser diode elements are preferably arranged on a surface of a second support substrate having an insulating property with a prescribed interval, and the third laser diode element is preferably arranged on a surface of a third support substrate separated from the second support substrate. According to this structure, the third laser diode element can be further easily electrically separated from the first and second laser diode elements by arranging the third laser diode element on the surface of the third support substrate different from the second support substrate arranged with the first and second laser diode elements, and hence deterioration of the third laser diode element having the longer lasing wavelength can be further suppressed.

In this case, the third support substrate preferably has conductivity, the package is preferably conductive, the third laser diode element preferably includes at least a first electrode, and the first electrode of the third laser diode element is preferably electrically connected to the package through the third support substrate. According to this structure, no wire for connecting the first electrode of the third laser diode element and the package is required and hence the number of wires can be reduced. The number of wires is reduced and hence wire distribution can be simplified. A surge current is temporarily held in the conductive package, whereby the surge current can be inhibited from rapidly flowing through the third laser diode element. Thus, deterioration of the third laser diode element can be suppressed.

In the aforementioned laser diode device according to the first aspect, each of the first and second laser diode elements preferably includes at least a first electrode, and the first electrodes of the first and second laser diode elements are preferably electrically connected to each other. According to this structure, whereby a common terminal and wire can be used for the first electrodes of the first and second laser diode elements, and hence the numbers of terminals and wires can be reduced. The number of wires is reduced and hence wire distribution can be simplified.

In this case, either positive potentials or negative potentials are preferably applied to the first electrodes of the first and second laser diode elements. According to this structure, the first electrodes of the first and second laser diode elements are connected to the power sources having the same polarity and the first and second laser diode elements can be operated.

In the aforementioned laser diode device according to the first aspect, the first and second laser diode elements are preferably formed on a surface of the same substrate. According to this structure, the first and second laser diode elements may not be separately bonded, and hence an interval between a luminous point of the first laser diode element and a luminous point of the second laser diode element can be further correctly positioned.

In the aforementioned laser diode device according to the first aspect, the third laser diode element is preferably arranged in the vicinity of an end of the package. According to this structure, the third laser diode element can be easily arranged to be electrically separated from the first and second laser diode elements as compared with a case where the third laser diode element is arranged in the vicinity of the center of the package.

In the aforementioned laser diode device provided with the first and second electrodes of the third laser diode element separately, the first and second electrodes of the first laser diode element are preferably provided separately from the first and second electrodes of the second laser diode element. According to this structure, deterioration of the third laser diode element due to a surge current generated when operating the first and second laser diode elements can be suppressed and deterioration of the first and second laser diode elements can be suppressed.

An optical apparatus according to a second aspect of the present invention comprises a laser diode device stored in a conductive package, a first power source having a plurality of electric power supply terminals, a second power source, and a third power source, wherein the laser diode device includes a first laser diode element including first and second electrodes, a second laser diode element including first and second electrodes, and a third laser diode element including at least a first electrode and having a longer lasing wavelength than the first and second laser diode elements, wherein the first electrode of the third laser diode element is electrically directly connected to the package, and the first and second electrodes of the first and second laser diode elements are not electrically directly connected to the package, the third laser diode element is operated by the first power source, and the first power source applies one of either positive potentials or negative potentials to the first electrodes of the first and second laser diode elements, and the second and third power sources, respectively, apply the other of either positive potentials or negative potentials to the second electrodes of the first and second laser diode elements, so that the first and second laser diode elements are operated.

In the optical apparatus according to the second aspect of the present invention, as hereinabove described, the first electrode of the third laser diode element is electrically directly connected to the conductive package, and the first and second electrodes of the first and second laser diode elements are not electrically directly connected to the package, whereby the third laser diode element, which is made of a material with a smaller band gap than the first and second laser diode elements and hence has a low device resistance to easily flow a current through the active layer, can be electrically separated, and hence the third laser diode element having the longer lasing wavelength can be inhibited from deterioration due to a surge current generated when operating the first and second laser diode elements. A surge current caused by static electricity or the like is temporarily held in the conductive package, whereby the surge current can be inhibited from rapidly flowing through the third laser diode element. Thus, deterioration of the third laser diode element can be suppressed.

In the aforementioned optical apparatus according to the second aspect, the third laser diode element is operated by the first power source, the first power source applies one of either positive potentials or negative potentials to the first electrodes of the first and second laser diode elements, and the second and third power sources, respectively, apply the other of either positive potentials or negative potentials to the second electrodes of the first and second laser diode elements, so that the first and second laser diode elements are operated, whereby the first and second laser diode elements having high operation voltages can be operated by the first power source used in the third laser diode element having a long lasing wavelength and a low operation voltage and the second and third power sources applying potentials reversed in polarity to the first power source.

In the aforementioned optical apparatus according to the second aspect, the third laser diode element preferably includes first and second electrodes, and the first and second electrodes of the third laser diode element are preferably provided separately from the first and second electrodes of the first laser diode element and the first and second electrodes of the second laser diode element. According to this structure, the third laser diode element can be easily electrically separated from the first and second laser diode elements, and hence the surge current from the first and second laser diode elements can be inhibited from flowing through the third laser diode element.

In the aforementioned optical apparatus according to the second aspect, the first laser diode element is preferably a blue laser diode element, the second laser diode element is preferably a green laser diode element, and the third laser diode element is preferably a red laser diode element. According to this structure, the red laser diode element, which is made of the material with the small band gap and hence has a low device resistance to easily flow a current through the active layer, can be electrically separated in the optical apparatus comprising the RGB three-wavelength laser diode device, and hence the red laser diode element can be inhibited from deterioration due to a surge current generated when operating the blue and green laser diode elements having higher operation voltages.

In the aforementioned optical apparatus according to the second aspect, at least one of the first and second laser diode elements and the third laser diode element are preferably substantially simultaneously lase or alternately lase in time series. When at least one of the first and second laser diode elements and the third laser diode element substantially simultaneously lase or alternately lase in time series, a surge current caused in the first or second laser diode element is radiated outside through a portion having a low resistance. In other words, a surge current easily flows through the third laser diode element which has a small band gap and hence has a low device resistance. On the other hand, the third laser diode element is not electrically directly connected to the first and second laser diode elements in the present invention, whereby the third laser diode element during operation can be effectively inhibited from deterioration due to the surge current.

A display apparatus according to a third aspect of the present invention, a laser diode device including a first laser diode element, a second laser diode element and a third laser diode element having a longer lasing wavelength than the first and second laser diode elements, wherein the first, second and third laser diode elements are arranged in a package, and the third laser diode element is not electrically connected to the first and second laser diode elements and modulation means for modulating light from the laser diode device.

In the display apparatus according to the third aspect of the present invention, as hereinabove described, the third laser diode element having the longer lasing wavelength than the first and second laser diode elements is not electrically connected to the first and second laser diode elements, whereby the third laser diode element, which is made of the material with the smaller band gap than the first and second laser diode elements and hence has a low device resistance to easily flow a current through the active layer, can be electrically separated, and hence a desirable image can be displayed by modulating light by the modulation means with the laser diode device capable of suppressing deterioration of the third laser diode element having a long lasing wavelength due to a surge current caused when operating the first and second laser diode elements.

The aforementioned display apparatus according to the third aspect preferably further comprises a first power source having a plurality of electric power supply terminals, a second power source, and a third power source, wherein each of the first and second laser diode elements includes a first electrode and a second electrode, and the third laser diode element includes at least a first electrode, and the third laser diode element includes at least a first electrode, the package is conductive, the first electrode of the third laser diode element is electrically directly connected to the package, and the first and second electrodes of the first and second laser diode elements are not electrically directly connected to the package, the third laser diode element is operated by the first power source, the first power source applies one of either positive potentials or negative potentials to the first electrodes of the first and second laser diode elements, and the second and third power sources, respectively, apply the other of either positive potentials or negative potentials to the second electrodes of the first and second laser diode elements, so that the first and second laser diode elements are operated. According to this structure, a surge current caused by static electricity or the like is temporarily held in the conductive package, and hence the surge current can be inhibited from rapidly flowing through the third laser diode element. Thus, deterioration of the third laser diode element can be suppressed. The third laser diode element is operated by the first power source, the first power source applies one of either positive potentials or negative potentials to the first electrodes of the first and second laser diode elements, and the second and third power sources, respectively, apply the other of either positive potentials or negative potentials to the second electrodes of the first and second laser diode elements, so that the first and second laser diode elements are operated, whereby the first and second laser diode elements having high operation voltages can be operated by the first power source used in the third laser diode element having a long lasing wavelength and a low operation voltage and the second and third power sources applying potentials reversed in polarity to the first power source.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram of a structure of a laser diode device according to a first embodiment of the present invention as viewed from a direction perpendicular to a light-emitting direction;

FIG. 2 is a sectional view showing the structure of the laser diode device taken along the line 1000-1000 in FIG. 1;

FIG. 3 is a schematic diagram showing an electrical connection state of the laser diode device according to the first embodiment shown in FIG. 1;

FIG. 4 is a diagram of a structure of a laser diode device according to a second embodiment of the present invention as viewed from a direction perpendicular to a light-emitting direction;

FIG. 5 is a sectional view showing the structure of the laser diode device taken along the line 2000-2000 in FIG. 4;

FIG. 6 is a schematic diagram showing an electrical connection state of the laser diode device according to the second embodiment shown in FIG. 4;

FIG. 7 is a diagram of a structure of a laser diode device according to a first modification according to the second embodiment of the present invention as viewed from a direction perpendicular to a light-emitting direction;

FIG. 8 is a sectional view showing a structure of the laser diode device taken along the line 3000-3000 in FIG. 7;

FIG. 9 is a schematic diagram showing an electrical connection state of the laser diode device according to the first modification of the second embodiment shown in FIG. 7;

FIG. 10 is a schematic diagram showing an electrical connection state of an optical apparatus comprising the laser diode device according to the first modification of the second embodiment shown in FIG. 7;

FIG. 11 is a schematic diagram showing a projector comprising the optical apparatus according to the first modification of the second embodiment shown in FIG. 10, in which laser elements are periodically lighted in time series;

FIG. 12 is a timing chart showing a state in which a control unit according to the first modification of the second embodiment shown in FIG. 11 transmits signals in time series;

FIG. 13 is a schematic diagram showing a projector comprising the optical apparatus according to the first modification of the second embodiment shown in FIG. 10, in which the laser elements are substantially simultaneously lighted;

FIG. 14 is a diagram of a structure of a laser diode device according to a second modification according to the second embodiment of the present invention as viewed from a direction perpendicular to a light-emitting direction;

FIG. 15 is a sectional view showing a structure of the laser diode device taken along the line 4000-4000 in FIG. 14;

FIG. 16 is a diagram of a structure of a laser diode device according to a third embodiment of the present invention as viewed from a direction perpendicular to a light-emitting direction;

FIG. 17 is a sectional view showing a structure of the laser diode device taken along the line 5000-5000 in FIG. 16;

FIG. 18 is a schematic diagram showing an electrical connection state of the laser diode device of the third embodiment shown in FIG. 16;

FIG. 19 is a diagram of a structure of a laser diode device according to a fourth embodiment of the present invention as viewed from a direction perpendicular to a light-emitting direction;

FIG. 20 is a sectional view showing a structure of the laser diode device taken along the line 6000-6000 in FIG. 19;

FIG. 21 is a schematic diagram showing an electrical connection state of the laser diode device of the fourth embodiment shown in FIG. 19;

FIG. 22 is a sectional view showing a structure of a conventional laser diode device; and

FIG. 23 is a schematic diagram showing an electrical connection state of the conventional laser diode device shown in FIG. 22.

### DESCRIPTION OF THE PREFERRED EMBODIMENTS

Embodiments of the present invention will be hereinafter described with reference to the drawings.

### First Embodiment

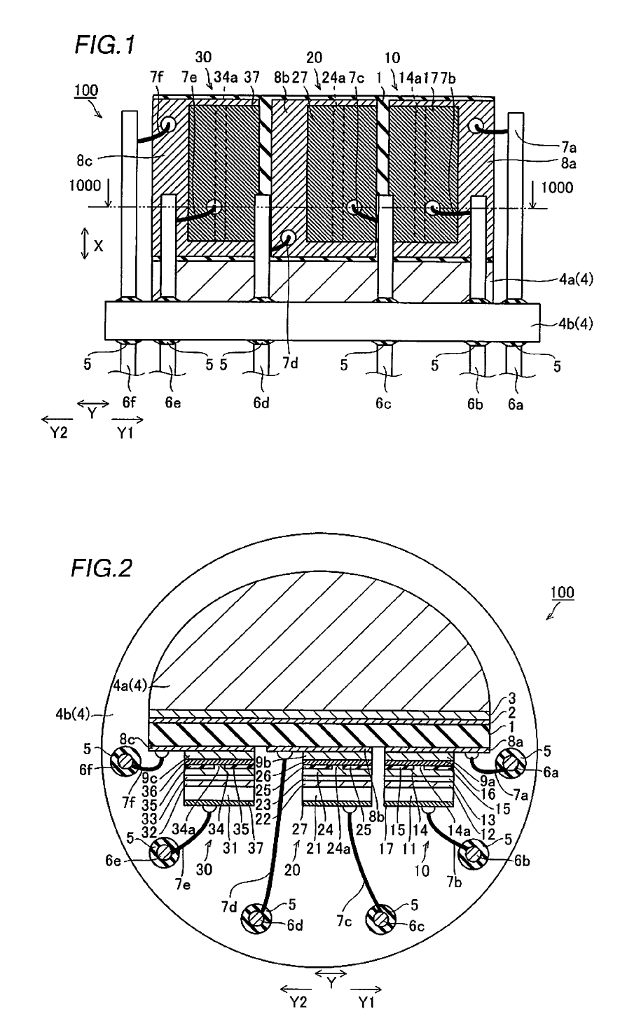

A structure of a laser diode device 100 according to a first embodiment of the present invention will be now described with reference to FIGS. 1 to 3.

In the laser diode device 100 according to the first embodiment of the present invention, a blue laser diode element 10 having an lasing wavelength of about 440 nm and a green laser diode element 20 having an lasing wavelength of about 520 nm and a red laser diode element 30 having an lasing wavelength of about 640 nm are bonded to a surface of a single submount 1 having an insulating property with prescribed intervals, as shown in FIGS. 1 and 2. Thus, the laser diode device 100 constitutes a RGB three-wavelength laser diode device. The blue laser diode element 10 may be formed to have lasing wavelengths in the range of about 435 nm to about 485 nm. The green laser diode element 20 may be formed to have lasing wavelengths in the range of about 500 nm to about 565 nm. The red laser diode element 30 may be formed to have lasing wavelengths in the range of about 610 nm to about 750 nm. An operation voltage of the red laser diode element 30 is lower than an operation voltage of the blue laser diode element 10 and an operation voltage of the green laser diode element 20. The blue, green and red laser diode elements 10, 20 and 30 are examples of the “first laser diode element”, the “second laser diode element” and the “third laser diode element” in the present invention, respectively.

The laser diode device 100 is formed to be usable as a light source for display. In other words, the laser diode device 100 is so formed that the blue, green and red laser diode elements 10, 20 and 30 substantially simultaneously lase or alternately lase in time series, to be usable as the light source for display. Thus, the laser diode device 100 is formed to be usable as a light source for display capable of displaying a plurality of colors including white.

The blue laser diode element 10 is bonded in the vicinity of an end of the submount 1 on a direction Y1 side, and the red laser diode element 30 is bonded in the vicinity of the submount 1 on a direction Y2 side. In other words, the blue laser diode element 10 and the red laser diode element 30 are bonded in the vicinity of ends of a package 4 described later, respectively. The green laser diode element 20 is bonded in the vicinity of a center of the submount 1 in a direction Y between the blue laser diode element 10 and the red laser diode element 30.

As shown in FIG. 2, the submount 1 is made of ceramic having high thermal conductivity and is bonded to a conductive support base 4a through a conductive layer 2 containing Au and a conductive fusion layer 3 made of a solder containing AuSn. This support base 4a may be made of Cu or Fe having high thermal conductivity and having a surface provided with an Au plating. The support base 4a is integrally bonded to a conductive stem body 4b. The conductive support base 4a and stem body 4b are components of the package 4. Thus, the blue, green and red laser diode elements 10, 20 and 30 are arranged in the single package 4. The package 4 is grounded. The submount 1 is an example of the “first support substrate” in the present invention.

As shown in FIG. 1, the stem body 4b is mounted with lead terminals 6a, 6b, 6c, 6d, 6e and 6f successively from the direction Y1 side through the insulating rings 5. The lead terminals 6a, 6b, 6c, 6d, 6e and 6f are electrically separated from each other and separated from the stem body 4b by the insulating rings 5. First ends of conductive wires 7a, 7b, 7c, 7d, 7e and 7f made of Au are connected to the lead terminals 6a, 6b, 6c, 6d, 6e and 6f, respectively.

As shown in FIG. 2, metal layers 8a, 8b and 8c containing Au are formed successively from the direction Y1 side on a surface, bonded with the blue, green and red laser diode elements 10, 20 and 30, of the submount 1. The metal layers 8a, 8b and 8c are formed so as not to be in contact with each other. Thus, the metal layers 8a, 8b and 8c are not electrically connected to each other.

Conductive fusion layers 9a , 9b and 9c made of solder containing AuSn having high thermal conductivity are formed on surfaces of the metal layers 8a, 8b and 8c. The fusion layers 9a , 9b and 9c, respectively are provided for bonding the blue, green and red laser diode elements 10, 20 and 30 to the submount 1. Thus, the metal layer 8a is electrically connected to a p-side electrode 16, described later, of the blue laser diode element 10 through the fusion layer 9a . The metal layer 8b is electrically connected to a p-side electrode 26, described later, of the green laser diode element 20 through the fusion layer 9b. The metal layer 8c is electrically connected to a p-side electrode 36, described later, of the red laser diode element 30 through the fusion layer 9c. The fusion layers 9a , 9b and 9c are not electrically connected to each other.

As shown in FIG. 1, second ends of the wires 7a, 7d and 7f are connected to the metal layers 8a, 8b and 8c, respectively. Thus, the metal layer 8a is electrically connected to the lead terminal 6a through the wire 7a. The metal layer 8b is electrically connected to the lead terminal 6d through the wire 7d. The metal layer 8c is electrically connected to the lead terminal 6f through the wire 7f.

As shown in FIG. 2, the blue laser diode element 10 has a structure in which an n-type cladding layer 12 made of n-type AlGaInN, an active layer 13 made of InGaN and a p-type cladding layer 14 made of p-type AlGaInN are stacked in this order on a surface of an n-type GaN substrate 11. The green laser diode element 20 has a structure in which an n-type cladding layer 22 made of n-type AlGaInN, an active layer 23 made of InGaN and a p-type cladding layer 24 made of p-type AlGaInN are stacked in this order on a surface of an n-type InGaN substrate 21. The red laser diode element 30 has a structure in which an n-type cladding layer 32 made of n-type AlGaInP, an active layer 33 made of AlGaInP and a p-type cladding layer 34 made of p-type AlGaInP are stacked in this order on a surface of an n-type GaAs substrate 31. The active layers 13, 23 and 33 maybe formed by single-layer structures, single quantum well (SQW) structures formed by alternately stacking two barrier layers (not shown) and a well layer (not shown), or multiple quantum well (MQW) structures formed by alternately stacking a plurality of barrier layers (not shown) and a plurality of well layers (not shown).

The p-type cladding layers 14, 24 and 34 have ridge portions 14a, 24a and 34a formed on substantially central portions of the elements and planar portions extending on both sides (direction Y) of the ridge portions 14a, 24a and 34a. As shown in FIG. 1, the ridge portions 14a, 24a and 34a are formed to extend along a cavity direction (direction X). In other words, the blue, green and red laser diode elements 10, 20 and 30 are formed to have structures of ridge waveguide laser devices.

As shown in FIG. 2, current blocking layer 15, 25 and 35 made of SiO₂ are so formed as to cover planar portions of the p-type cladding layers 14, 24 and 34 and side surfaces of the ridge portions 14a, 24a and 34a. The p-side electrodes 16, 26 and 36 made of Au are separately formed on surfaces of the ridge portions 14a, 24a and 34a and the current blocking layers 15, 25 and 35, respectively. The p-side contact layers for improving contact characteristics with the p-side electrodes 16, 26 and 36 may be provided on upper portions of the p-type cladding layers 14, 24 and 34 constituting the ridge portions 14a, 24a and 34a. An n-side electrode 17 containing Au is formed on a surface of the n-type GaN substrate 11. An n-side electrode 27 containing Au is formed on a surface of the n-type InGaN substrate 21. An n-side electrode 37 containing Au is formed on a surface of the n-type GaAs substrate 31. In other words, the n-side electrodes 17, 27 and 37 are separately formed to each other. The p-side electrodes 16, 26 and 36 are example of the “first electrode” and the n-side electrodes 17, 27 and 37 are example of the “second electrode” in the present invention.

According to the first embodiment, the n-side electrode 17 of the blue laser diode element 10 is electrically connected to the lead terminal 6b through the wire 7b, as shown in FIG. 1. At this time, the wire 7b and the lead terminal 6b are electrically separated from other wires (wires 7a, 7c, 7d, 7e and 7f) and other lead terminals (lead terminals 6a, 6c, 6d, 6e and 6f). The n-side electrode 27 of the green laser diode element 20 is electrically connected to the lead terminal 6c through the wire 7c. At this time, the wire 7c and the lead terminal 6c are electrically separated from other wires (wires 7a, 7b, 7d, 7e and 7f) and other lead terminals (lead terminals 6a, 6b, 6d, 6e and 6f). The n-side electrode 37 of the red laser diode element 30 is electrically connected to the lead terminal 6e through the wire 7e. At this time, the wire 7e and the lead terminal 6e are electrically separated from other wires (wires 7a, 7b, 7c, 7d and 7f) and other lead terminals (lead terminals 6a, 6b, 6c, 6d and 6f). Thus, the n-side electrode 17 of the blue laser diode element 10, the n-side electrode 27 of the green laser diode element 20 and the n-side electrode 37 of the red laser diode element 30 are not electrically connected to each other.

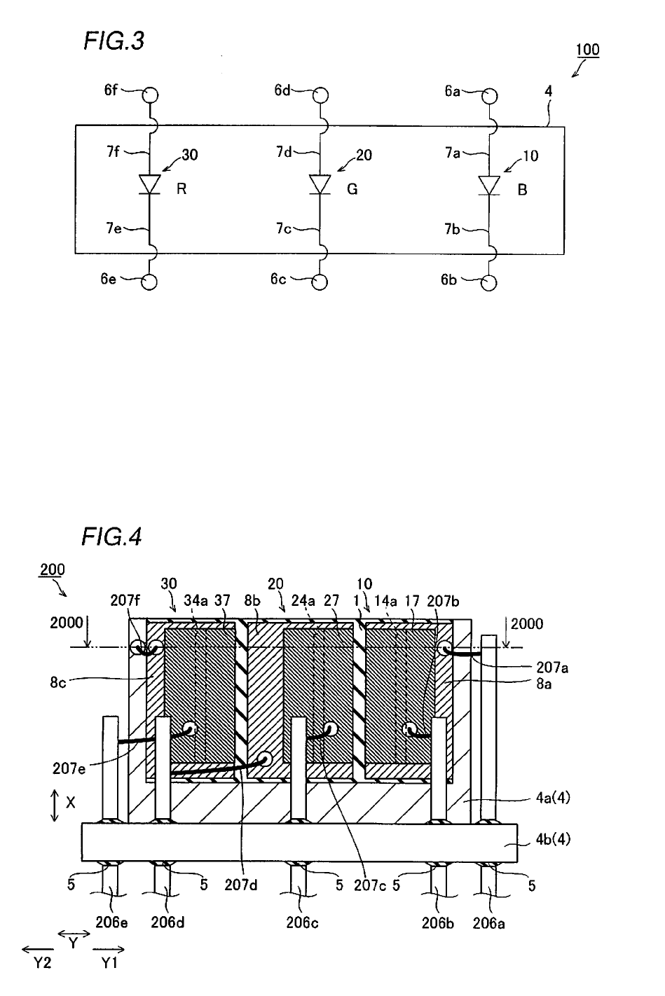

According to the first embodiment, the p-side electrode 16 of the blue laser diode element 10 is electrically connected to the lead terminal 6a through the fusion layer 9a , the metal layer 8a and the wire 7a (see FIG. 1), as shown in FIG. 2. At this time, the fusion layer 9a , the metal layer 8a, the wire 7a and the lead terminal 6a are electrically separated from other fusion layers (fusion layers 9b and 9c), other metal layers (metal layers 8b and 8c), other wires (wires 7b, 7c, 7d, 7e and 7f) and other lead terminals (lead terminals 6b, 6c, 6d, 6e and 6f). The p-side electrode 26 of the green laser diode element 20 is electrically connected to the lead terminal 6d through the fusion layer 9b, the metal layer 8b and the wire 7d. At this time, the fusion layer 9b, the metal layer 8b, the wire 7d and the lead terminal 6d are electrically separated from other fusion layers (fusion layers 9a and 9c), other metal layers (metal layers 8a and 8c), other wires (wires 7a, 7b, 7c, 7e and 7f) and other lead terminals (lead terminals 6a, 6b, 6c, 6e and 6f). The p-side electrode 36 of the red laser diode element 30 is electrically connected to the lead terminal 6f through the fusion layer 9c, the metal layer 8c and the wire 7f (see FIG. 1). At this time, the fusion layer 9c, the metal layer 8c, the wire 7f and the lead terminal 6f are electrically separated from other fusion layers (fusion layers 9a and 9b), other metal layers (metal layers 8a and 8b), other wires (wires 7a, 7b, 7c, 7d and 7e) and other lead terminals (lead terminals 6a, 6b, 6c, 6d and 6e). Thus, the p-side electrode 16 of the blue laser diode element 10, the p-side electrode 26 of the green laser diode element 20, the p-side electrode 36 of the red laser diode element 30 are not electrically connected to each other. Consequently, the blue, green and red laser diode elements 10, 20 and 30 are not electrically connected to each other, as shown in FIG. 3.

According to the first embodiment, as hereinabove described, the red laser diode element 30 having a longer lasing wavelength than the blue and green laser diode elements 10 and 20 is electrically separated from the blue and green laser diode elements 10 and 20, whereby the red laser diode element 30, which is made of the material with a small band gap and hence has a low device resistance to easily flow a current through the active layer 33, can be electrically separated in the RGB three-wavelength laser diode device, and the red laser diode element 30 having the longer lasing wavelength can be inhibited from deterioration due to a surge current generated when operating the blue and green laser diode elements 10 and 20 having higher operation voltages.

According to the first embodiment, the p-side electrodes 16, 26 and 36 are separately formed to each other, and the n-side electrodes 17, 27 and 37 are separately formed to each other, whereby the red laser diode element 30 can be easily electrically separated from the blue and green laser diode elements 10 and 20, and hence the surge current from the blue and green laser diode elements 10 and 20 can be inhibited from flowing through the red laser diode element 30. Additionally, deterioration of the blue and green laser diode elements 10 and 20 can be also suppressed.

According to the first embodiment, the blue, green and red laser diode elements 10, 20 and 30 are bonded on the surface of the single submount 1 having the insulating property, whereby the red laser diode element 30 can be further reliably electrically separated from the blue and green laser diode elements 10 and 20 by the submount 1 having the insulating property, and hence deterioration of the red laser diode element 30 having the longer lasing wavelength can be further suppressed.

According to the first embodiment, the red laser diode element 30 is electrically separated from the blue and green laser diode elements 10 and 20, whereby the surge current generated in the blue and green laser diode elements 10 and 20 made of materials with large band gaps and having high device resistances and the operation voltage can be prevented from flowing through the red laser diode element 30 made of the material with the small band gap and having the low device resistance in use for a display or the like also when the blue, green and red laser diode elements 10, 20 and 30 substantially simultaneously lase or alternately lase in time series, and hence the red laser diode element 30 in an operating state can be effectively inhibited from deterioration due to the surge current.

According to the first embodiment, the red laser diode element 30 is bonded in the vicinity of the end of the package 4 (support base 4a), whereby the red laser diode element 30 can be easily arranged to be electrically separated from the blue and green laser diode elements 10 and 20 as compared with a case where the red laser diode element 30 is arranged in the vicinity of the center of the package 4 (support base 4a).

### Second Embodiment

A second embodiment will be now described with reference to FIG. 1 and FIGS. 4 to 6. In a laser diode device 200 according to the second embodiment, a red laser diode element 30 is electrically connected to a support base 4a of a package 4 through a fusion layer 9c, a metal layer 8c and a wire 207f dissimilarly to the aforementioned first embodiment.

In the laser diode device 200 according to the second embodiment of the present invention, lead terminals 206a, 206b, 206c, 206d and 206e are mounted successively from a direction Y1 side on a conductive stem body 4b of the package 4 which is grounded, as shown in FIG. 4. First ends of conductive wires 207a, 207b, 207c, 207d and 207e are connected to the lead terminals 206a, 206b, 206c, 206d and 206e, respectively. In other words, in the second embodiment, no lead terminal 6f (see FIG. 1) of the aforementioned first embodiment is mounted.

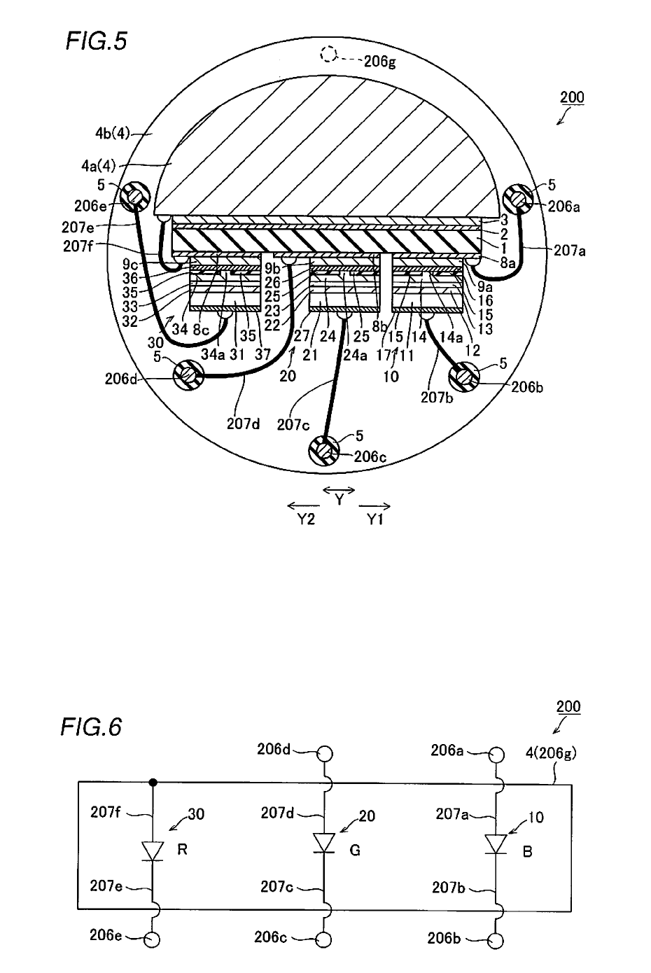

According to the second embodiment, a second end of the wire 207f is connected to the metal layer 8c, as shown in FIG. 5. The metal layer 8c is electrically connected to a p-side electrode 36 of the red laser diode element 30 through the fusion layer 9c. First end of the wire 207f is connected on the conductive support base 4a of the package 4. A terminal 206g is electrically connected to the stem body 4b. Thus, the p-side electrode 36 of the red laser diode element 30 is electrically connected to the package 4 and the terminal 206g through the fusion layer 9c, the metal layer 8c and the wire 207f. Consequently, the package 4 is grounded, whereby a surge current caused by static electricity or the like can be released from the laser diode device 200 while being inhibited from flowing to the red laser diode element 30, and hence deterioration of the red laser diode element 30 can be suppressed. The p-side electrode 36 is an example of the “first electrode” in the present invention.

According to the second embodiment, p-side electrodes 16 and 26 of blue and green laser diode elements 10 and 20 are electrically separated from the support base 4a by a submount 1 having an insulating property. Thus, the p-side electrodes 16 and 26 of the blue and green laser diode elements 10 and 20 are electrically separated from the p-side electrode 36 of the red laser diode element 30. Additionally, n-side electrodes 17 and 27 of the blue and green laser diode elements 10 and 20 are electrically separated from an n-side electrode 37 of the red laser diode element 30 similarly to the aforementioned first embodiment. Consequently, the blue, green and red laser diode elements 10, 20 and 30 are electrically separated from each other as shown in FIG. 6. The remaining structure of the second embodiment is similar to that of the aforementioned first embodiment.

According to the second embodiment, as hereinabove described, the p-side electrode 36 of the red laser diode element 30 is electrically connected to the conductive package 4, whereby a surge current caused by static electricity or the like is temporarily held in the conductive package 4, and hence the surge current can be inhibited from rapidly flowing through the red laser diode element 30. Thus, deterioration of the red laser diode element 30 can be suppressed.

According to the second embodiment, as hereinabove described, the package 4 is grounded, whereby the surge current can be promptly released from the laser diode device 200, and hence the surge current can be reliably inhibited from rapidly flowing through the red laser diode element 30. The remaining effects of the second embodiment are similar to those of the aforementioned first embodiment.

### First Modification of Second Embodiment

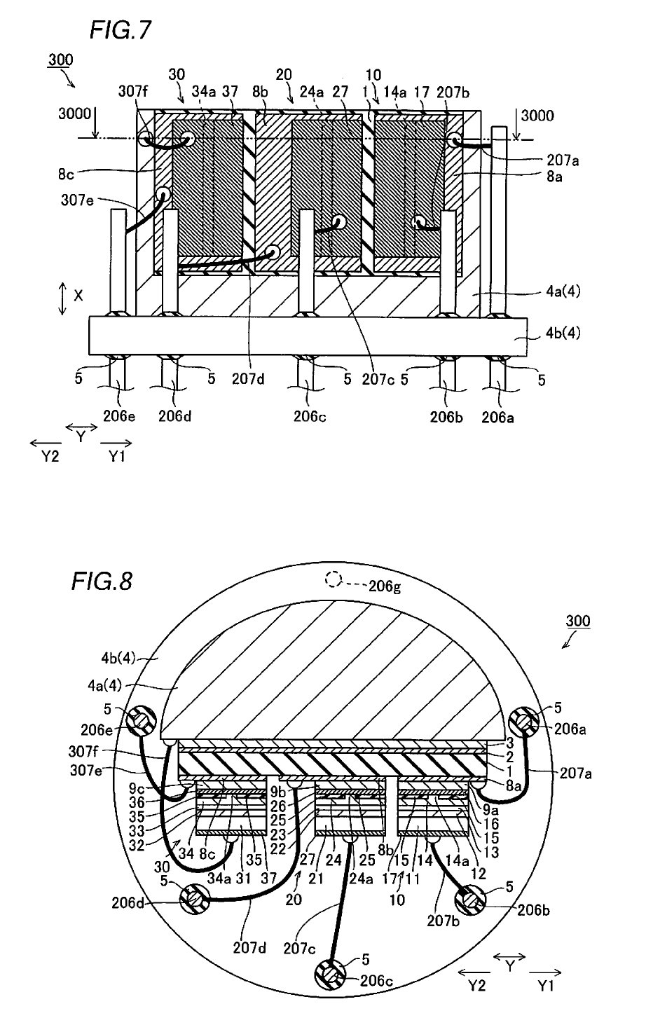

A first modification of the second embodiment will be now described with reference to FIGS. 7 to 13. In a laser diode device 300 according to the first modification of the second embodiment, a second end of a conductive wire 307e is connected to a metal layer 8c and a first end of a conductive wire 307f is connected to a surface of a support base 4a, dissimilarly to the aforementioned second embodiment. An optical apparatus 340 including the laser diode device 300 and projectors 350 and 360 each comprising the optical apparatus 340 will be described. The projectors 350 and 360 are examples of the “display apparatus” in the present invention.

The laser diode device 300 according to the first modification of the second embodiment will be described with reference to FIGS. 7 to 9.

In the laser diode device 300 according to the first modification of the second embodiment of the present invention, first end of the conductive wire 307e is connected to a lead terminal 206e, as shown in FIG. 7. A second end of the wire 307e is connected to the metal layer 8c electrically connected to a p-side electrode 36 of a red laser diode element 30 through a fusion layer 9c, as shown in FIG. 8.

As shown in FIG. 8, a first end of the wire 307f is connected to the surface of the conductive support base 4a of the package 4, and a second end of the wire 307f is connected to an n-side electrode 37. Thus, the n-side electrode 37 of the red laser diode element 30 is electrically connected to the package 4 and a lead terminal 206g through the fusion layer 9c, the metal layer 8c and the wire 307f. Consequently, the package 4 is grounded, whereby a surge current caused by static electricity or the like can be released from the laser diode device 300 while being inhibited from flowing to the red laser diode element 30, and hence deterioration of the red laser diode element 30 can be suppressed. The n-side electrode 37 is an example of the “first electrode” in the present invention.

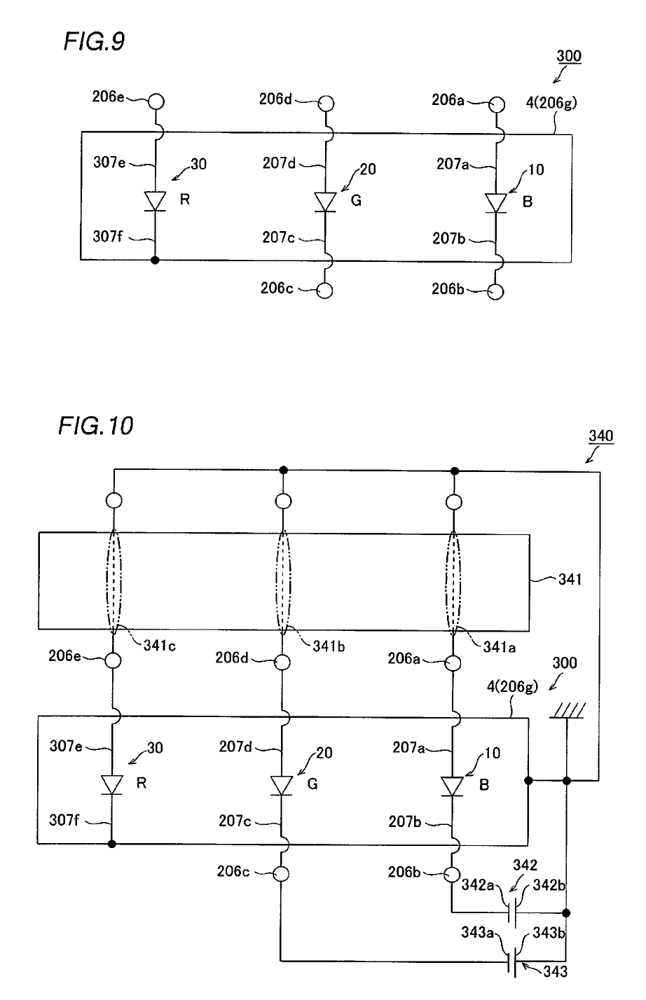

According to the first modification of the second embodiment, p-side electrodes 16 and 26 of blue and green laser diode elements 10 and 20 are electrically separated from the support base 4a by a submount 1 having an insulating property similarly to the aforementioned second embodiment. Thus, the p-side electrodes 16, 26 and 36 of the blue, green and red laser diode elements 10, 20 and 30 are electrically separated from each other. Additionally, n-side electrodes 17, 27 and 37 of the blue, green and red laser diode elements 10, 20 and 30 are not electrically connected to each other. Consequently, the blue, green and red laser diode elements 10, 20 and 30 are electrically separated from each other, as shown in FIG. 9. The remaining structure of the first modification of the second embodiment is similar to that of the aforementioned second embodiment.

The optical apparatus 340 comprising the laser diode device 300 will be described with reference to FIGS. 8 and 10.

The optical apparatus 340 according to the first modification of the second embodiment of the present invention is provided with the laser diode device 300, a driver integrated circuit (IC) 341 capable of supplying a pulse voltage or a stationary voltage, and DC power sources 342 and 343, as shown in FIG. 10. The driver IC 341 is an example of the “first power source” in the present invention. The DC power sources 342 and 343 are examples of the “second power source” and the “third power source” in the present invention, respectively.

The p-side electrode 16 (see FIG. 8) of the blue laser diode element 10 of the laser diode device 300 is electrically connected to a lead terminal 206a through a wire 207a, and the n-side electrode 17 (see FIG. 8) is electrically connected to a lead terminal 206a through a wire 207a. The p-side electrode 26 (see FIG. 8) of the green laser diode element 20 of the laser diode device 300 is electrically connected to a lead terminal 206d through a wire 207d, and the n-side electrode 27 (see FIG. 8) is electrically connected to a lead terminal 206c through a wire 207c. In other words, the blue and green laser diode elements 10 and 20 are not electrically directly connected to the conductive package 4.

The p-side electrode 36 (see FIG. 8) of the red laser diode element 30 of the laser diode device 300 is electrically connected to the lead terminal 206e through the wire 307e, and the n-side electrode 37 (see FIG. 8) is electrically connected to the package 4 and the lead terminal 206g through the wire 307f. The blue, green and red laser diode elements 10, 20 and 30 are electrically separated from each other.

According to the first modification of the second embodiment, the driver IC 341 has channels (electric power supply terminal) 341a, 341b and 341c capable of independently supplying power of about 2 V to about 3 V to the lead terminals of the laser diode device 300. A first terminal of the channel 341a is electrically connected to the lead terminal 206a. A first terminal of the channel 341b is electrically connected to the lead terminal 206d. A first terminal of the channel 341c is electrically connected to the lead terminal 206e. Second terminals of the channels 341a, 341b and 341c are all grounded.

The driver IC 341 applies a positive potential (about 2 V to about 3 V) to the lead terminal 206e in the red laser diode element 30 of the laser diode device 300, so that a potential difference (about 2 V to about 3 V) between the lead terminal 206e and the grounded lead terminal 206g is generated. Thus, a current flows through the red laser diode element 30, thereby operating the red laser diode element 30.

A negative terminal 342a of the DC power source 342 is connected to the lead terminal 206b, and a positive terminal 342b is electrically connected to the package 4 and the lead terminal 206g which are grounded. The DC power source 342 is so formed as to apply a potential of about −3 V to the lead terminal 206b. Thus, the driver IC 341 applies a positive potential (about 2 V to about 3 V) to the lead terminal 206a and the DC power source 342 applies a negative potential (about −3 V) to the lead terminal 206b in the blue laser diode element 10 of the laser diode device 300, so that a potential difference (about 5 V to about 6 V) between the lead terminals 206a and 206b is caused. Consequently, a current flows through the blue laser diode element 10, thereby operating the blue laser diode element 10.

A negative terminal 343a of the DC power source 343 is connected to the lead terminal 206c, and a positive terminal 343b is electrically connected to the package 4 and the lead terminal 206g which are grounded. The DC power source 343 is so formed as to apply a potential of about −2.5 V to the lead terminal 206c. Thus, the driver IC 341 applies a positive potential (about 2 V to about 3 V) to the lead terminal 206d and the DC power source 342 applies a negative potential (about −2.5 V) to the lead terminal 206c in the green laser diode element 20 of the laser diode device 300, so that a potential difference (about 4.5 V to about 5.5 V) between the lead terminals 206d and 206c is caused. Consequently, a current flows through the green laser diode element 20, thereby operating the green laser diode element 20.

The projector 350 comprising the optical apparatus 340 including the laser diode device 300, in which the laser elements are lighted in time series will be now described with reference to FIGS. 10 to 12.

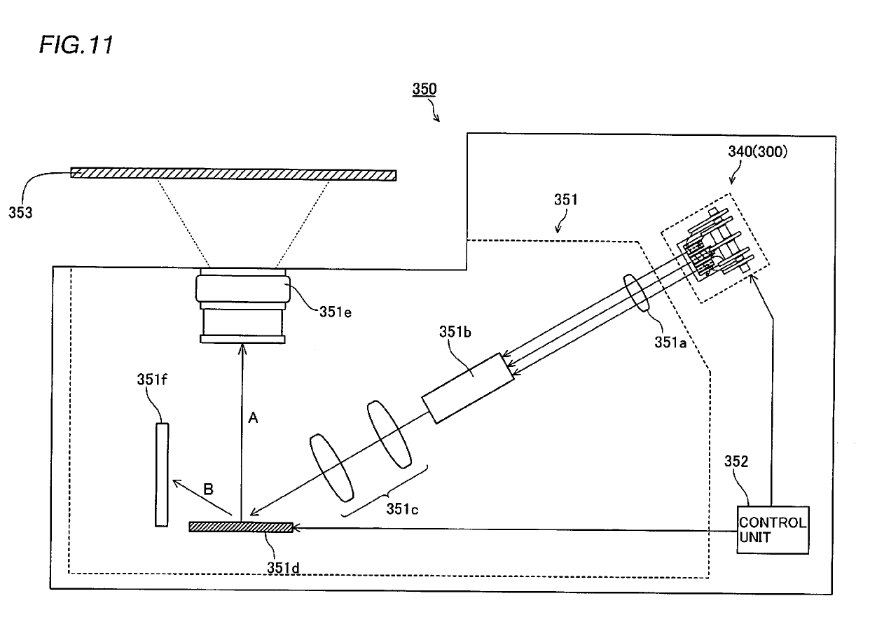

The projector 350 according to the first modification of the second embodiment of the present invention is provided with the optical apparatus 340 including the laser diode device 300, an optical system 351 including a plurality of optical components and a control unit 352 controlling the optical apparatus 340 and the optical system 351, as shown in FIG. 11. Thus, light from the laser diode device 300 is modulated by the optical system 351 and thereafter projected on a screen 353. The optical system 351 is an example of the “modulation means” in the present invention.

As shown in FIG. 11, each light emitted from the laser diode device 300 is converted to parallel light by a lens 351a and thereafter incident on a light pipe 351b in the optical system 351.

An inner surface of the light pipe 351b is a mirror surface, and light proceeds in the light pipe 351b while repeating reflection on the inner surface of the light pipe 351b. At this time, light intensity distribution of each color emitted from the light pipe 351b is uniformized by multiple refection in the light pipe 351b. The light emitted from the light pipe 351b is incident on a digital micro-mirror device (DMD) 351d through a relay optical system 351c.

The DMD device 351d is constituted by a small mirror group arranged in the form of a matrix. The DMD device 351d has a function of representing (modulating) gradation of each pixel by switching a reflection direction of light on each pixel position, a first direction A for going toward the projection lens 351e or a second direction B for departing from the projection lens 351e. Light reflected in the first direction A by the DMD device 351d projected on a screen 353 through the projection lens 351e. A light absorber 351f absorbs light reflected in the second direction B by the DMD device 351d without being incident on the projection lens 351e.

In the projector 350, the control unit 352 so controls that the driver IC 341 (see FIG. 10) of the optical apparatus 340 supplies a pulse voltage to the laser diode device 300, whereby the blue, green and red laser diode elements 10, 20 and 30 (see FIG. 10) are alternately operated in time series per element. The DMD device 351d of the optical system 351 is so formed as to modulate light in accordance with gradation of each pixel while synchronizing the light with operation of the blue, green and red laser diode elements 10, 20 and 30 by the control unit 352.

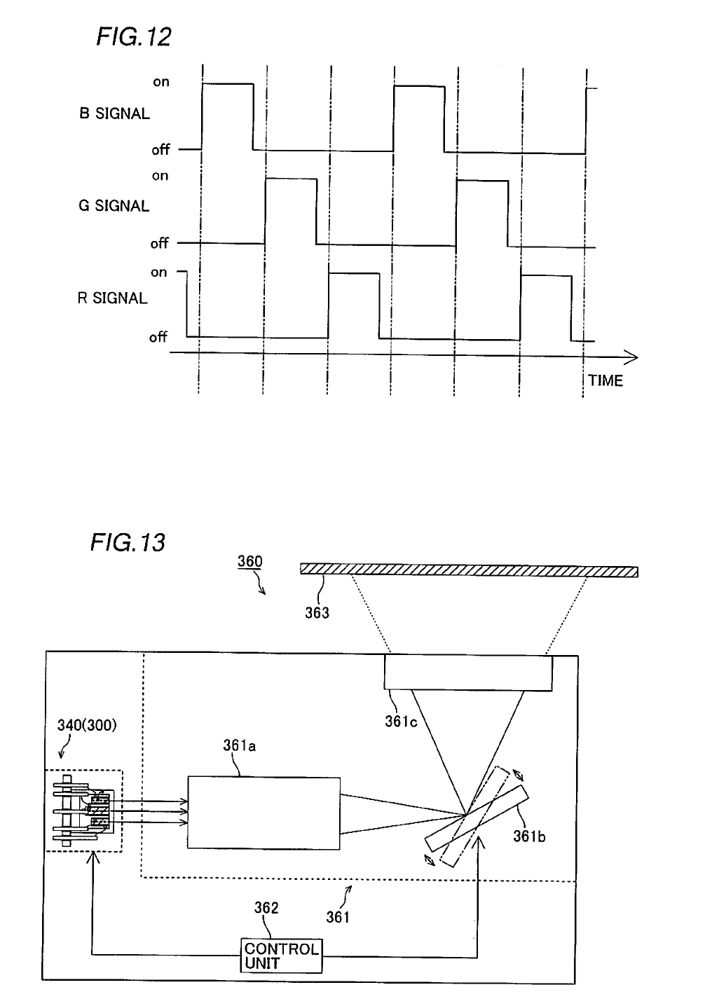

More specifically, a signal B regarding operation of the blue laser diode element 10 (see FIG. 10), a signal G regarding operation of the green laser diode element 20 (see FIG. 10) and a signal R regarding operation of the red laser diode element 30 (see FIG. 10) transmit so as not to overlap with each other as shown in FIG. 12, and are outputted to the driver IC 341 by the control unit 352 shown in FIG. 11. Image signals B, G and R are outputted to the DMD device 351d in synchronization with the signals B, G and R, respectively. During this time, the DC power sources 342 and 343 (see FIG. 10) of the optical apparatus 340 supply a voltage reversed in polarity to the driver IC 341.

Thus, blue light of the blue laser diode element 10 is emitted according to the signal B, and the DMD device 351d modulates the blue light according to the image signal B at this timing. Green light of the green laser diode element 20 is emitted according to the signal G outputted next to the signal B, and the DMD device 351d modulates the green light according to the image signal G at this timing. Red light of the red laser diode element 30 is emitted according to the signal R outputted next to the signal G, and the DMD device 351d modulates the red light according to the image signal R at this timing. Thereafter, blue light of the blue laser diode element 10 is emitted according to the signal B outputted next to the signal R, and the DMD device 351d modulates the blue light according to the image signal B at this timing again. The aforementioned operation is repeated, so that an image by laser beam irradiation according to the signals B, G and R is projected on the screen 353.

The projector 360 comprising the optical apparatus 340 including the laser diode device 300, in which the laser elements are substantially simultaneously lighted, will be now described with reference to FIGS. 10 and 13.

The projector 360 according to the first modification of the second embodiment of the present invention is provided with the optical apparatus 360 including the laser diode device 300, an optical system 361 including a plurality of optical components and a control unit 362 controlling the optical apparatus 340 and the optical system 361, as shown in FIG. 13. Thus, light from the laser diode device 300 is modulated by the optical system 361 and thereafter projected on a screen 363 or the like. The optical system 361 is an example of the “modulation means” in the present invention.

In the optical system 361, each light emitted from the laser diode device 300 is shaped by a light shaping portion 361a and thereafter incident upon a scan mirror 361b. The scan mirror 361b is so formed that an angle is controlled by the control unit 362, in order to project a two-dimensional image on a screen 363. Thus, light is reflected by the scan mirror 361b at a prescribed angle at prescribed time, thereby two-dimensionally scanning while modulating light so as to project light on the screen in time division. The light reflected by the scan mirror 361b is projected on the screen 363 through a projection lens 361c.

In the projector 360, the control unit 362 so controls that the driver IC 341 (see FIG. 10) of the optical apparatus 340 supplies stationary power to the laser diode device 300, so that the blue, green and red laser diode elements 10, 20 and 30 (see FIG. 10) of the laser diode device 300 substantially simultaneously lase. The control unit 362 controls intensity of each light of the blue, green and red laser diode elements 10, 20 and 30 of the laser diode device 300, so that color phase, brightness or the like of pixels projected on the screen 363 is controlled.

The scan mirror 361b of the optical system 361 two-dimensionally scans while modulating light in synchronization with operation of the laser diode device 300 by the control unit 362. Thus, a desirable image is projected on the screen 363 by the control unit 362.

According to the first modification of the second embodiment, as hereinabove described, the n-side electrode 37 of the red laser diode element 30 is electrically connected to the conductive package 4, whereby a surge current caused by static electricity or the like is temporarily held in the conductive package 4, and hence the surge current can be inhibited from rapidly flowing through the red laser diode element 30. Thus, deterioration of the red laser diode element 30 can be suppressed.

According to the first modification of the second embodiment, the package 4 is grounded and a positive potential is applied to the lead terminal 206e electrically connected to the p-side electrode 36, whereby the red laser diode element 30 can be operated. Thus, the laser diode device 300 can be operated at a high speed in time series by a general pulsed power supply circuit.

According to the first modification of the second embodiment, in the optical apparatus 340, the driver IC 341 applies a positive potential to the lead terminal 206e in the red laser diode element 30 so that the red laser diode element 30 is operated, while the driver IC 341 applies positive potentials to the lead terminal 206a and 206d in the blue and green laser diode elements 10 and 20 and the DC power sources 342 and 343 apply to negative potentials to the lead terminal 206b and 206c so that the blue and green laser diode elements 10 and 20 are operated, whereby the blue and green laser diode elements 10 and 20 having high operation voltages can be operated by the driver IC 341 used in the red laser diode element 30 having a long lasing wavelength and a low operation voltage and the DC power sources 342 and 343 applying potentials reverse in polarity to the driver IC 341.

According to the first modification of the second embodiment, the driver IC 341 of the optical apparatus 340 controls to supply a pulse voltage to the laser diode device 300 in the projector 350, whereby the blue, green and red laser diode elements 10, 20 and 30 of the laser diode device 300 are divided in time series and alternately operated per element, whereby a surge current caused in the blue or green laser diode element 10 or 20 is easily radiated outside through a portion having a low resistance when the elements are divided in time series and alternately operated per element. Also in this case, the red laser diode element 30 is electrically separated from the blue and green laser diode elements 10 and 20, whereby the red laser diode element 30 during operation can be effectively inhibited from deterioration due to the surge current.

According to the first modification of the second embodiment, in the projector 360, the driver IC 341 of the optical apparatus 340 controls to supply a stationary voltage to the laser diode device 300, whereby the blue, green and red laser diode elements 10, 20 and 30 of the laser diode device 300 substantially simultaneously lase, whereby a surge current caused in the blue or green laser diode element 10 or 20 is easily radiated outside through the portion having a low resistance when the respective laser elements substantially simultaneously lase. Also in this case, the red laser diode element 30 is electrically separated from the blue and green laser diode elements 10 and 20, whereby the red laser diode element 30 during operation can be effectively inhibited from deterioration due to the surge current.

According to the first modification of the second embodiment, the projector 350 is provided with the optical apparatus 340 including the laser diode device 300 and the optical system 351, and the projector 360 is provided with the optical apparatus 340 including the laser diode device 300 and the optical system 361, whereby a desirable image can be displayed by modulating light by the optical systems 351 and 361 with the laser diode device 300 capable of suppressing deterioration of the red laser diode element 30 having a long lasing wavelength. The remaining effects of the first modification of the second embodiment are similar to those of the aforementioned second embodiment.

### Second Modification of Second Embodiment

A second modification of the second embodiment will be now described with reference to FIGS. 4, 14 and 15. In a laser diode device 400 according to the second modification of the second embodiment, blue and green laser diode elements 10 and 20 are set on a surface of a submount 401 having an insulating property, and a red laser diode element 30 is set on a surface of a conductive submount 470 different from the submount 401, dissimilarly to the aforementioned second embodiment.

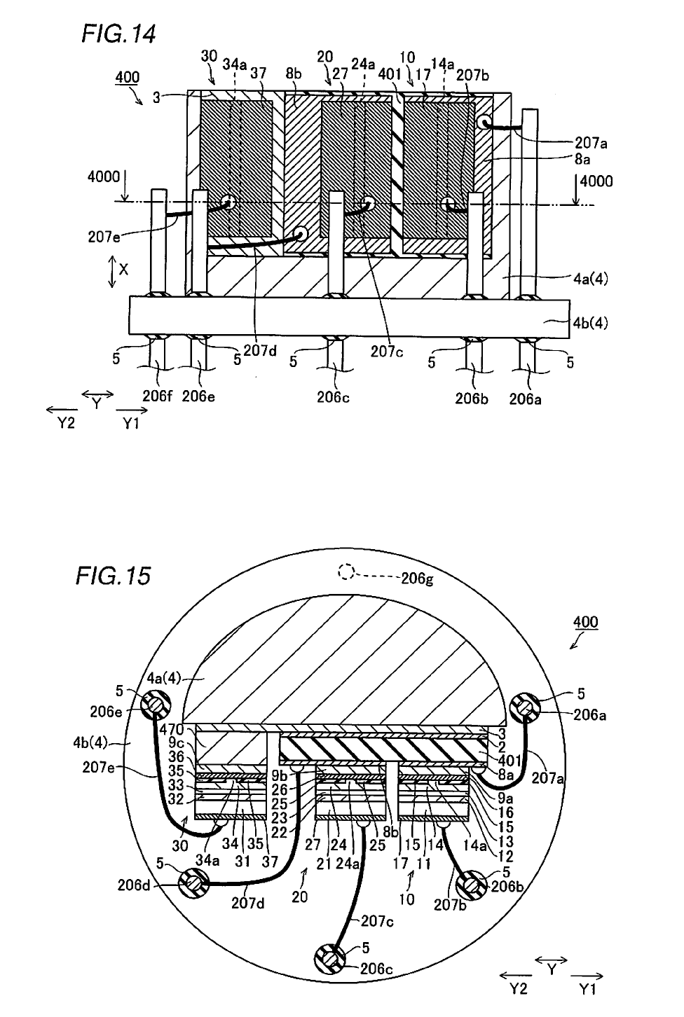

In the laser diode device 400 according to the second modification of the second embodiment of the present invention, the blue laser diode element 10 is bonded to the surface of the submount 401 having the insulating property on a direction Y1 side through a fusion layer 9a (see FIG. 15) and a metal layer 8a as shown in FIGS. 14 and 15. The green laser diode element 20 is bonded to the surface of the submount 401 having the insulating property on a direction Y2 side through a fusion layer 9b (see FIG. 15) and a metal layer 8b.

In the second modification of the second embodiment, the red laser diode element 30 is bonded on the surface of the conductive submount 470 through a fusion layer 9c as shown in FIG. 15. The submount 470 is separated from the submount 401 bonded with the blue and green laser diode elements 10 and 20 on the surface thereof with a prescribed interval. The submounts 401 and 470 are bonded to a conductive support base 4a through a conductive fusion layer 3. Thus, a p-side electrode 36 of the red laser diode element 30 is electrically connected to a package 4 (the support base 4a and a stem body 4b) and a terminal 206g through the fusion layer 9c, the submount 470 and the fusion layer 3. According to the second modification of the second embodiment, no metal layer 8c (see FIG. 4) and no wire 207f (see FIG. 4) of the aforementioned second embodiment are provided. The submount 401 is an example of the “second support substrate” in the present invention, and the submount 470 is an example of the “third support substrate” in the present invention. The remaining structure of the second modification of the second embodiment is similar to that of the aforementioned second embodiment.

According to the second modification of the second embodiment, as hereinabove described, the p-side electrode 36 of the red laser diode element 30 is electrically connected to the package 4 and the terminal 206g through the fusion layer 9c, the submount 470 and the fusion layer 3, whereby no wire 207f according to the aforementioned second embodiment is required and hence the number of wires can be reduced. The number of wires is reduced and hence wire distribution can be simplified. A surge current is temporarily held in the conductive package 4, whereby the surge current can be inhibited from rapidly flowing through the red laser diode element 30. Thus, deterioration of the red laser diode element 30 can be suppressed.

According to the second modification of the second embodiment, the submount 470 on which the red laser diode element 30 is bonded, thereof is separated from the submount 401 on which the blue and green laser diode elements 10 and 20 are bonded, thereof with the prescribed interval, whereby the red laser diode element 30 can be further easily electrically separated from the blue and green laser diode elements 10 and 20, and hence deterioration of the red laser diode element 30 having a long lasing wavelength can be further suppressed. The remaining effects of the second modification of the second embodiment are similar to those of the aforementioned second embodiment.

### Third Embodiment

A third embodiment will be described with reference to FIGS. 4 and 16 to 18. In a laser diode device 500 according to the third embodiment, p-side electrodes 16 and 26 of blue and green laser diode elements 10 and 20 are electrically connected to each other, dissimilarly to the aforementioned second embodiment.

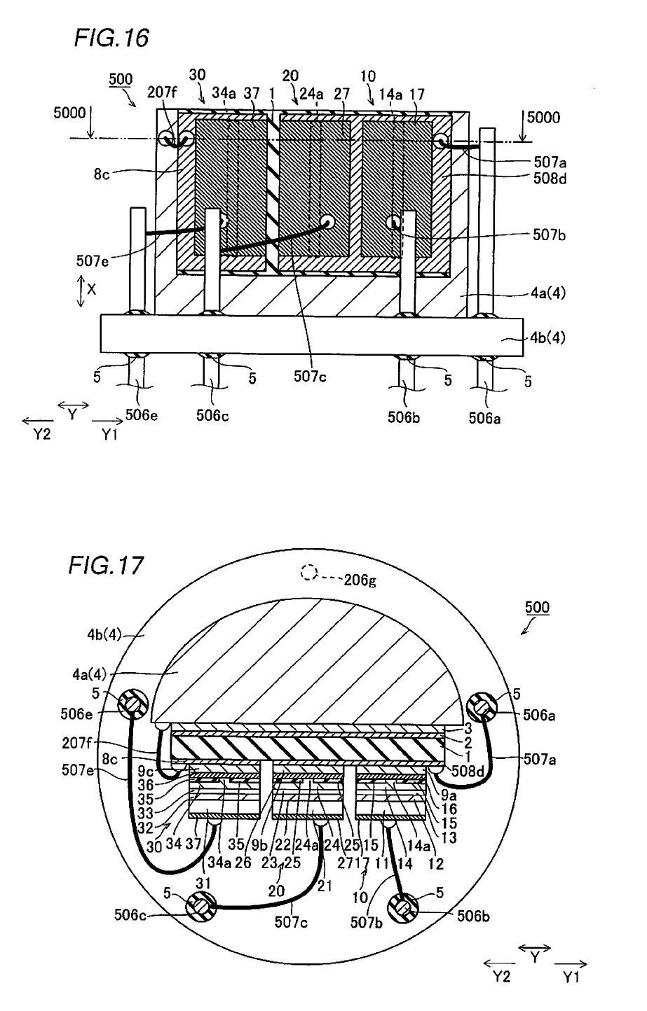

In the laser diode device 500 according to the third embodiment of the present invention, lead terminals 506a, 506b, 506c and 506e are mounted successively from a direction Y1 side on a stem body 4b of a package 4 which is grounded, as shown in FIG. 16. First ends of conductive wires 507a, 507b, 507c and 507e are connected to the lead terminals 506a, 506b, 506c and 506e, respectively. In other words, according to the third embodiment, no lead terminal 206d (see FIG. 4) and no wire 207d (see FIG. 4) according to the aforementioned second embodiment are mounted.

According to the third embodiment, a metal layer 508d is formed on a surface of the submount 1 on a direction Y1 side, as shown in FIGS. 16 and 17. The metal layer 508d is formed on the surface of the submount 1 to extend from an end on the direction Y1 side to a portion slightly closer to a direction Y2 side with respect to a center of the submount 1 in a direction Y. The metal layer 508d is not in contact with a metal layer 8c electrically connected to a red laser diode element 30.

As shown in FIG. 17, a fusion layer 9a bonding the blue laser diode element 10 to the surface of the submount 1 is formed on a surface of the metal layer 508d on the direction Y1 side and a fusion layer 9b bonding the green laser diode element 20 to the surface of the submount 1 is formed on a surface of the metal layer 508d on the direction Y2 side. Thus, the metal layer 508d is electrically connected to the p-side electrode 16 of the blue laser diode element 10 through the fusion layer 9a , and electrically connected to the p-side electrode 26 of the green laser diode element 20 through the fusion layer 9b. Consequently, the blue and green laser diode elements 10 and 20 can be operated by a power source having the same polarity (p-side). Second end of the wire 507a is connected to the metal layer 508d. The p-side electrodes 16 and 26 are examples of the “first electrode” in the present invention.

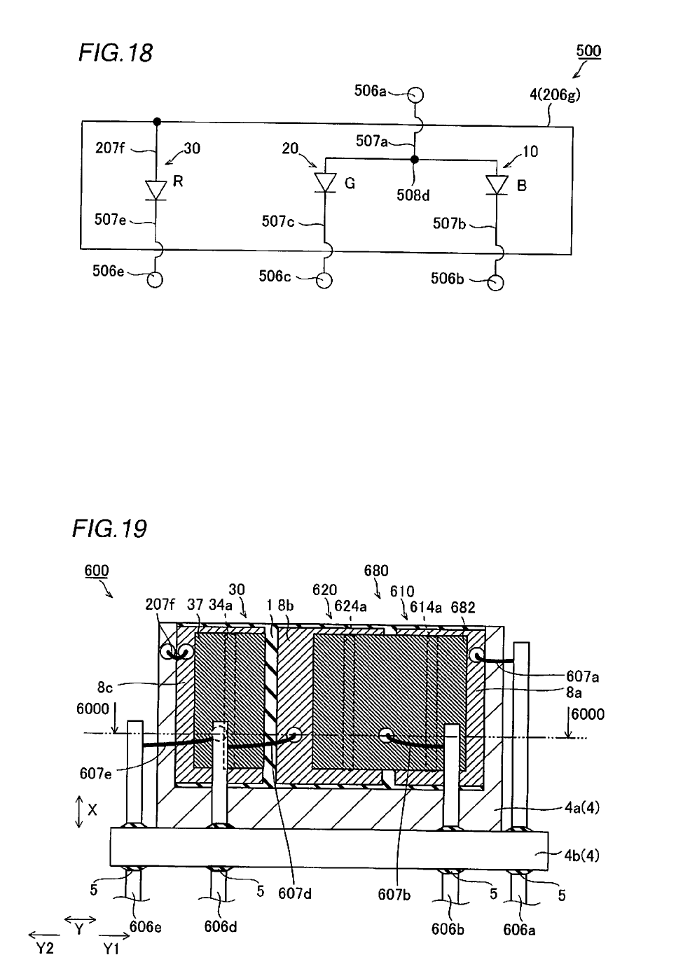

According to the third embodiment, the p-side electrodes 16 and 26 of the blue and green laser diode elements 10 and 20 are not electrically connected to a p-side electrode 36 of the red laser diode element 30. Similarly to the aforementioned second embodiment, n-side electrodes 17, 27 and 37 of the blue, green and red laser diode elements 10, 20 and 30 are not electrically connected to each other. Consequently, the blue and green laser diode elements 10 and 20 are electrically separated from the red laser diode element 30, and the p-side electrodes 16 and 26 of the blue and green laser diode elements 10 and 20 are electrically connected to the metal layer 508d to be electrically connected to each other, as shown in FIG. 18. The remaining structure of the third embodiment is similar to that of the aforementioned second embodiment.

According to the third embodiment, as hereinabove described, the p-side electrodes 16 and 26 of the blue and green laser diode elements 10 and 20 are electrically connected to each other, whereby a common terminal (506a) and wire (507a) can be used for the p-side electrodes 16 and 26 of the blue and green laser diode elements 10 and 20, and hence the numbers of terminals and wires can be reduced. The number of wires is reduced and hence wire distribution can be simplified. The p-side electrodes 16 and 26 of the blue and green laser diode elements 10 and 20 are connected to the power sources having the same polarity (positive polarity) and the blue and green laser diode elements 10 and 20 can be operated. The remaining effects of the third embodiment are similar to those of the aforementioned second embodiment.

### Fourth Embodiment

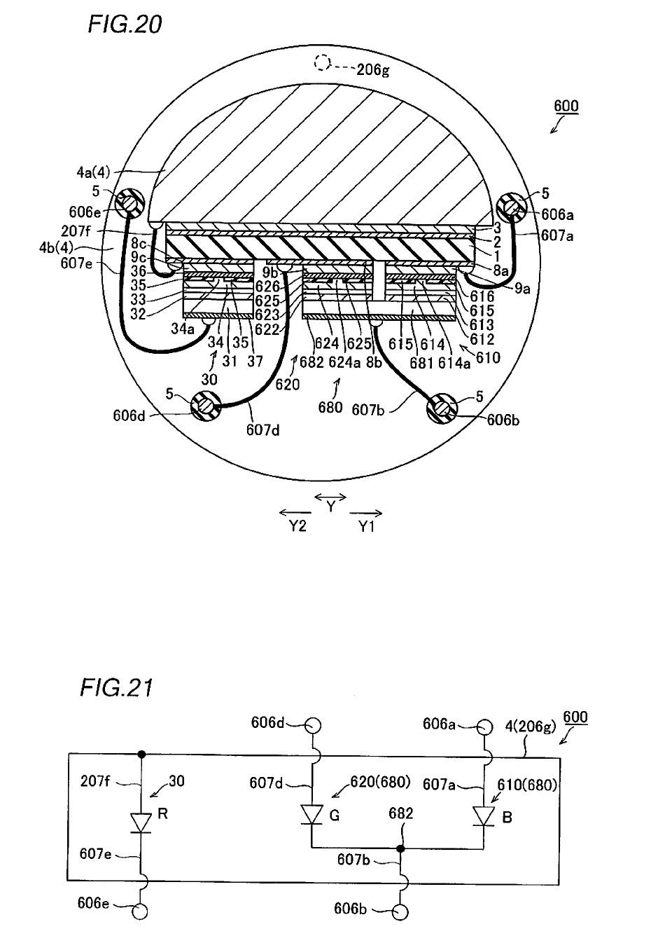

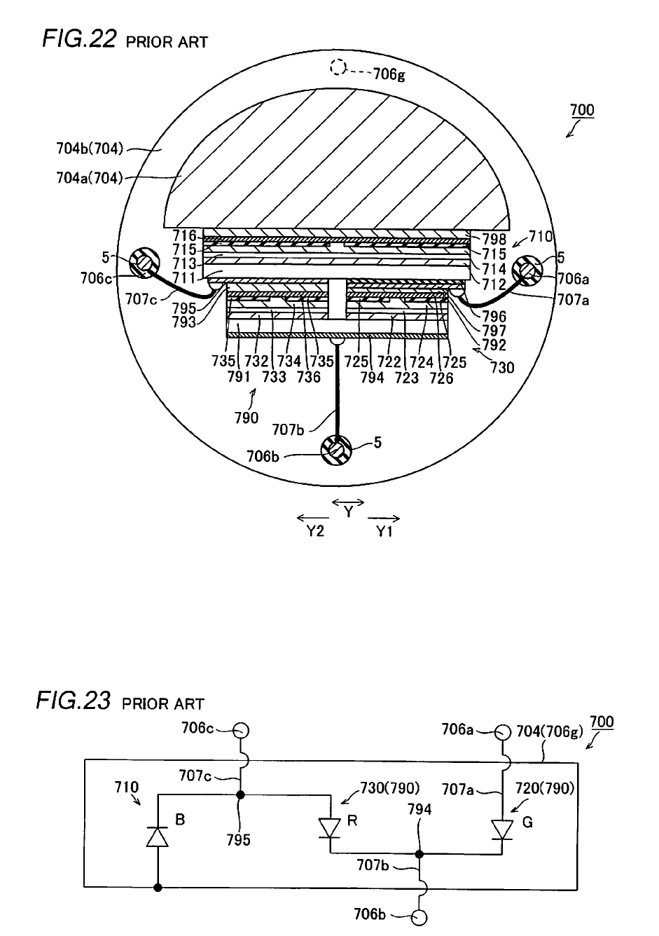

A fourth embodiment will be described with reference to FIGS. 4 and 19 to 21. In a laser diode device 600 according to the fourth embodiment, blue and green laser diode elements 610 and 620 are fabricated on a surface of a common n-type GaN substrate 681 and an n-side electrode (n-side electrode 682) of the blue laser diode element 610 and an n-side electrode (n-side electrode 682) of the green laser diode element 620 are common, dissimilarly to the aforementioned second embodiment. The blue and green laser diode elements 610 and 620 are examples of the “first laser diode element” and the “second laser diode element” in the present invention, respectively.

In the laser diode device 600 according to the fourth embodiment of the present invention, lead terminals 606a, 606b, 606d and 606e are mounted successively from a direction Y1 side on a conductive stem body 4b of a package 4 which is grounded, as shown in FIG. 19. First ends of conductive wires 607a, 607b, 607d and 607e are connected to the lead terminals 606a, 606b, 606d and 606e, respectively. In other words, according to the fourth embodiment, no lead terminal 206c (see FIG. 4) and no wire 207c (see FIG. 4) according to the aforementioned second embodiment are mounted.

According to the fourth embodiment, the blue and green laser diode elements 610 and 620 are fabricated on a surface of the common n-type GaN substrate 681 having an m-plane ((1-100) plane) surface which is a nonoplar plane capable of suppressing influence of a piezoelectric field dissimilarly to a case of having a c-plane ((0001) plane) surface. Thus, the blue and green laser diode elements 610 and 620 constitute a blue and green monolithic laser diode element portion 680. The n-type GaN substrate 681 is an example of the “substrate” in the present invention.

More specifically, the blue laser diode element 610 has a structure in which an n-type cladding layer 612, an active layer 613 and a p-type cladding layer 614 having a ridge portion 614a are stacked on a surface of the n-type GaN substrate 681 having the m-plane ((1-100) plane) surface. The green laser diode element 620 has a structure in which an n-type cladding layer 622, an active layer 623 and a p-type cladding layer 624 having a ridge portion 624a are stacked on the surface of the n-type GaN substrate 681.

Current blocking layers 615 and 625 made of SiO₂ are formed to cover the planar portions of the p-type cladding layers 614 and 624 and side surfaces of the ridge portions 614a and 624a. P-side electrodes 616 and 626 are formed on surfaces of the ridge portions 614a and 624a and the current blocking layers 615 and 625, respectively. P-side contact layers for improving contact characteristics with the p-side electrodes 616 and 626 may be provided on upper portions of the p-type cladding layers 614 and 624 constituting the ridge portions 614a and 624a, respectively.

The n-side electrode 682 is formed on the n-type GaN substrate 681. Thus, the n-side electrodes of the blue and green laser diode elements 610 and 620 are the common n-side electrode 682. In other words, the n-side electrodes (n-side electrode 682) of the blue and green laser diode elements 610 and 620 are electrically connected to each other. Consequently, the blue and green laser diode elements 610 and 620 can be operated by a power source having the same polarity (negative polarity). A second end of the wire 607b is connected to the n-side electrode 682. The n-side electrode 682 is an example of the “first electrode” in the present invention.

According to the fourth embodiment, the p-side electrodes 616 and 626 of the blue and green laser diode elements 610 and 620 and a p-side electrode 36 of a red laser diode element 30 are electrically connected from each other, similarly to the aforementioned second embodiment. The common n-side electrode 682 of the blue and green laser diode elements 610 and 620 are electrically separated from an n-side electrode 37 of the red laser diode element 30. Consequently, the blue and green laser diode elements 610 and 620 and the red laser diode element 30 are electrically separated from each other, and the blue and green laser diode elements 610 and 620 are electrically connected to each other on the n-side electrode 682, as shown in FIG. 21. The remaining structure of the fourth embodiment is similar to that of the aforementioned second embodiment.

According to the fourth embodiment, as hereinabove described, the n-side electrodes (n-side electrode 682) of the blue and green laser diode elements 610 and 620 are electrically connected, whereby a common terminal (606a) and wire (607a) can be used for the n-side electrode 628 of the blue and green laser diode elements 610 and 620, and hence the numbers of terminals and wires can be reduced. The number of wires is reduced and hence wire distribution can be simplified.

According to the fourth embodiment, the blue and green monolithic laser diode element portion 680 is constituted, whereby the blue and green laser diode elements 610 and 620 may not be separately bonded to the submount 1, and hence an interval between a luminous point of the blue laser diode element 610 and a luminous point of the green laser diode element 620 can be further correctly positioned. The remaining effects of the fourth embodiment are similar to those of the aforementioned second embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the laser diode device comprises the three laser diode elements of the blue, green and red laser diode elements in each of the aforementioned first to fourth embodiments, the present invention is not restricted to this but the laser diode device may be formed to comprise four or more laser diode elements. The laser diode device may be formed to comprise a blue-violet laser diode element in place of the blue laser diode element or comprise an infrared laser diode element in place of the red laser diode element.

While the p-side electrode of the red laser diode element is electrically connected to the package in each of the aforementioned third and fourth embodiments, the present invention is not restricted to this but the n-side electrode of the red laser diode element may not be electrically connected to the package, and the red laser diode element and the package may be electrically separated from each other in the structure of each of the third and fourth embodiments, similarly to the first embodiment.

While the package is grounded in each of the aforementioned first to fourth embodiments, the present invention is not restricted to this but the package may not be grounded.

While the laser diode device is formed by setting the blue, green and red laser diode elements on the submount in each of the aforementioned first to fourth embodiments, the present invention is not restricted to this but a plurality of laser diode elements may be stacked, thereby forming the laser diode device.

While the laser diode device is formed to be usable as the light source for display in each of the aforementioned first to fourth embodiments and the laser diode device is used for the projector comprising the optical apparatus including the laser diode device in the aforementioned first modification of the second embodiment, the present invention is not restricted to this but the laser diode device may be used as a light source of an optical pickup.

While the conductive support base and stem body constitute the package in the aforementioned first embodiment, the present invention is not restricted to this but the support base and the stem body may be formed by insulators having high thermal conductivity such as ceramics.

While the blue and green laser diode elements are formed by a nitride-based semiconductor layer such as AlGaN or InGaN in each of the aforementioned first to fourth embodiments, the present invention is not restricted to this but the blue and green laser diode elements may be formed by a nitride-based semiconductor layer made of AlN, InN, BN, TiN or alloyed semiconductors thereof, having a wurtzite structure.

While the blue laser diode element is set on the direction Yl side of the submount, the red laser diode element is set on the direction Y2 side of the submount, and the green laser diode element is set in the vicinity of the center of the submount between the blue and red laser diode elements in each of the aforementioned first to fourth embodiments, the present invention is not restricted to this but arrangement of the blue, green and red laser diode elements is not restricted. For example, the blue or red laser diode element may be set in the vicinity of the center of the submount.

While the red laser diode element is set on the surface of the conductive submount in the aforementioned second modification of the second embodiment, the present invention is not restricted to this but the red laser diode element may be set on the surface of the submount having the insulating property, and the p-side electrode of the red laser diode element and the conductive package may be connected by the wire.

While the red laser diode element is bonded in the vicinity of the end of the support base in each of the aforementioned first to fourth embodiments, the present invention is not restricted to this but the red laser diode element may be bonded in the vicinity of the center of the support base.

While the laser elements are substantially simultaneously lighted in the projector comprising the optical system having the scan mirror in the aforementioned first modification of the second embodiment, the present invention is not restricted to this but the laser elements may be periodically lighted in time series in the projector comprising the optical system having the scan mirror.

While the projector comprises the optical system having the DMD device in the aforementioned first modification of the second embodiment, the present invention is not restricted to this but the projector may be comprises two-dimensional modulation means such as an optical system having a liquid crystal panel, for example.

What is claimed is:

1. A laser diode device comprising:
a first laser diode element;
a second laser diode element; and
a third laser diode element having a longer lasing wavelength than said first and second laser diode elements, wherein
said first, second and third laser diode elements are arranged in a package, and said third laser diode element is not electrically connected to said first and second laser diode elements.

2. The laser diode device according to claim 1, wherein
each of said first, second and third laser diode elements includes a first electrode and a second electrode, and
said first and second electrodes of said third laser diode element are provided separately from said first and second electrodes of said first laser diode element and said first and second electrodes of said second laser diode element.

3. The laser diode device according to claim 1, wherein
said first laser diode element is a blue laser diode element, said second laser diode element is a green laser diode element, and said third laser diode element is a red laser diode element.

4. The laser diode device according to claim 1, wherein
at least one of said first and second laser diode elements and said third laser diode element substantially simultaneously lase or alternately lase in time series.

5. The laser diode device according to claim 1, wherein
said package is conductive,
said third laser diode element includes at least a first electrode, and
said first electrode of said third laser diode element is electrically connected to said package.

6. The laser diode device according to claim 5, wherein
said package is grounded.

7. The laser diode device according to claim 1, wherein
said first, second and third laser diode elements are arranged on a surface of a first support substrate having an insulating property with prescribed intervals.

8. The laser diode device according to claim 1, wherein
said first and second laser diode elements are arranged on a surface of a second support substrate having an insulating property with a prescribed interval, and
said third laser diode element is arranged on a surface of a third support substrate separated from said second support substrate.

9. The laser diode device according to claim 8, wherein
said third support substrate is conductive,
said package is conductive,
said third laser diode element includes at least a first electrode, and
said first electrode of said third laser diode element is electrically connected to said package through said third support substrate.

10. The laser diode device according to claim 1, wherein
each of said first and second laser diode elements includes at least a first electrode, and
said first electrodes of said first and second laser diode elements are electrically connected to each other.

11. The laser diode device according to claim 10, wherein
either positive potentials or negative potentials are applied to said first electrodes of said first and second laser diode elements.

12. The laser diode device according to claim 1, wherein
said first and second laser diode elements are formed on a surface of the same substrate.

13. The laser diode device according to claim 1, wherein
said third laser diode element is arranged in the vicinity of an end of said package.

14. The laser diode device according to claim 2, wherein
said first and second electrodes of said first laser diode element are provided separately from said first and second electrodes of said second laser diode element.

15. An optical apparatus comprising:
a laser diode device stored in a conductive package;
a first power source having a plurality of electric power supply terminals;
a second power source; and
a third power source, wherein
said laser diode device includes:
a first laser diode element including first and second electrodes,
a second laser diode element including first and second electrodes, and
a third laser diode element including at least a first electrode and having a longer lasing wavelength than said first and second laser diode elements, wherein
said first electrode of said third laser diode element is electrically directly connected to said package, and said first and second electrodes of said first and second laser diode elements are not electrically directly connected to said package,
said third laser diode element is operated by said first power source, and
said first power source applies one of either positive potentials or negative potentials to said first electrodes of said first and second laser diode elements, and said second and third power sources, respectively, apply the other of either positive potentials or negative potentials to said second electrodes of said first and second laser diode elements, so that said first and second laser diode elements are operated.

16. The optical apparatus according to claim 15, wherein said third laser diode element includes first and second electrodes, and
said first and second electrodes of said third laser diode element are provided separately from said first and second electrodes of said first laser diode element and said first and second electrodes of said second laser diode element.

17. The optical apparatus according to claim 15, wherein
said first laser diode element is a blue laser diode element, said second laser diode element is a green laser diode element, and said third laser diode element is a red laser diode element.

18. The optical apparatus according to claim 15, wherein
at least one of said first and second laser diode elements and said third laser diode element substantially simultaneously lase or alternately lase in time series.

19. A display apparatus comprising:
a laser diode device including a first laser diode element, a second laser diode element and a third laser diode element having a longer lasing wavelength than said first and second laser diode elements, wherein said first, second and third laser diode elements are arranged in a package, and said third laser diode element is not electrically connected to said first and second laser diode elements; and
modulation means for modulating light from said laser diode device.

20. The display apparatus according to claim 19, further comprising:
a first power source having a plurality of electric power supply terminals;
a second power source; and
a third power source, wherein
each of said first and second laser diode elements includes a first electrode and a second electrode, and said third laser diode element includes at least a first electrode,
said package is conductive,
said first electrode of said third laser diode element is electrically directly connected to said package, and said first and second electrodes of said first and second laser diode elements are not electrically directly connected to said package,
said third laser diode element is operated by said first power source,
said first power source applies one of either positive potentials or negative potentials to said first electrodes of said first and second laser diode elements, and said second and third power sources, respectively, apply the other of either positive potentials or negative potentials to said second electrodes of said first and second laser diode elements, so that said first and second laser diode elements are operated.
